(19) United States
(12) Patent Application Publication
(10) Pub. No.: US 2024/0421251 A1
(43) Pub. Date: Dec. 19, 2024

(54) LIGHT-EMITTING DIODE CHIP AND LIGHT-EMITTING DEVICE

(71) Applicant: XIAMEN SAN'AN OPTOELECTRONICS CO., LTD., Xiamen (CN)

(72) Inventors: Gong CHEN, Xiamen (CN); Yashu ZANG, Xiamen (CN); Chunhsien LEE, Xiamen (CN); Weichun TSENG, Xiamen (CN); Chunlan HE, Xiamen (CN); Chung-Ying CHANG, Xiamen (CN); Jiming CAI, Xiamen (CN); Shao-hua HUANG, Xiamen (CN)

(21) Appl. No.: 18/736,550

(22) Filed: Jun. 7, 2024

(30) Foreign Application Priority Data
Jun. 16, 2023 (CN) 2023107170835

(51) Int. Cl. H01L 33/14; H01L 33/38; H01L 33/62

(52) U.S. Cl. CPC H01L 33/145; H01L 33/38; H01L 33/62

(57) ABSTRACT

A LED chip includes a current blocking layer that includes a first portion and a second portion and a current expansion layer defined with a first opening; and the first portion is disposed in the first opening of the current expansion layer. A first gap is defined between the first portion and the current expansion layer; a second gap is defined between the first portion and the second portion; an electrode structure covers the first portion and is in contact with an upper surface of a semiconductor light-emitting sequence stacking layer through the first gap; at least a portion of an extension strip is formed on the second portion of the current blocking layer and the current expansion layer; a part of an edge of the first opening of the current expansion layer is disposed on the second portion of the current blocking layer.

This application claims priority to Chinese Patent Application No.202310717083.5, filed to China National Intellectual Property Administration (CNIPA) on Jun. 16, 2023, which is herein incorporated by reference in its entirety.

### TECHNICAL FIELD

The disclosure relates to the technical field of semiconductor devices, and more particularly to a light-emitting diode (LED) chip and a light-emitting device.

### BACKGROUND

Light emitting diode (LED) has advantages of high efficiency, long service life, small size, low power consumption, etc., and is widely applied to indoor and outdoor illumination, screen display, backlight sources, etc. A common structure of an electrode of a LED chip generally includes two parts, i.e., an electrode pad and an electrode extension strip, and a lower surface of the electrode pad is at least in contact with a current expansion layer disposed at an edge of the lower surface of the electrode pad. Meanwhile, a current blocking layer is disposed below the electrode pad and the electrode extension strip, and the current blocking layer blocks a current from being transmitted vertically downward from the electrode, thereby improving distribution uniformity of the current. However, during a subsequent wire bonding process, a force exerted on the current blocking layer in an contact area between the electrode pad and the electrode extension strip is increased, so that the current blocking layer is very easy to break to result in failure on the wire bonding, and at the same time, blocking effects of the current blocking layer on the current is weakened, thereby affecting the reliability of the LED.

### SUMMARY

In view of the above-mentioned defects and deficiencies in the related art, the disclosure provides a LED chip and a light-emitting device, which can improve a capability of wire bonding of the LED chip, improve the blocking effect of a current blocking layer, and promote distribution uniformity of a current.

In an aspect, the disclosure provides a LED chip.

The LED chip includes: a semiconductor light-emitting sequence stacking layer; a current blocking layer that is formed on the semiconductor light-emitting sequence stacking layer and includes a first portion and a second portion; a current expansion layer that is formed on both of the semiconductor light-emitting sequence stacking layer and the second portion of the current blocking layer and defines a first opening, where the first portion of the current blocking layer is disposed in the first opening of the current expansion layer; and an electrode structure that includes an electrode pad and an extension strip.

A first gap is defined between the first portion of the current blocking layer and the current expansion layer; a second gap is defined between the first portion of the current blocking layer and the second portion of the current blocking layer; and the electrode structure is disposed to cover the first portion of the current blocking layer and is in contact with an upper surface of the semiconductor light-emitting sequence stacking layer through the first gap; at least a portion of the extension strip is formed on both of the second portion of the current blocking layer and the current expansion layer; and a part of an edge of the first opening of the current expansion layer is disposed on the second portion of the current blocking layer.

In another aspect, the disclosure provides a LED chip, including: a semiconductor light-emitting sequence stacking layer; a current blocking layer that is formed on the semiconductor light-emitting sequence stacking layer and includes a first portion and a second portion; a current expansion layer that is formed on both of the semiconductor light-emitting sequence stacking layer and the second portion of the current blocking layer and defines a first opening, where the first portion of the current blocking layer is disposed in the first opening of the current expansion layer; and an electrode structure that includes an electrode pad and an extension strip, the electrode pad of which is disposed on the first portion of the current blocking layer, and the extension strip of which is formed on both of the second portion of the current blocking layer and the current expansion layer.

A first gap is defined between the first portion of the current blocking layer and the current expansion layer; a second gap is defined between the first portion of the current blocking layer and the second portion of the current blocking layer; and the electrode structure is disposed to cover the first portion of the current blocking layer and is in contact with an upper surface of the semiconductor light-emitting sequence stacking layer through the first gap; and an absolute value of a width difference between a width of the first gap and a width of the second gap is not greater than 15 micrometers (μm).

In still another aspect, the disclosure provides a light-emitting device, including a circuit substrate and a light-emitting component disposed on the circuit substrate, and the light emitting component includes the LED chip provided by the disclosure.

As described above, the LED chip and the light-emitting device of the disclosure have the following beneficial effects.

In the disclosure, the electrode structure of the LED chip includes the electrode pad and the extension strip; the current blocking layer includes the first portion and the second portion; and the current expansion layer is formed on both of the semiconductor light-emitting sequence stacking layer and the second portion of the current blocking layer, the current expansion layer defines the first opening, and the first portion of the current blocking layer is disposed in the first opening of the current expansion layer. Moreover, the first gap is defined between the first portion of the current blocking layer and the current expansion layer, the second gap is defined between the second portion of the current blocking layer and the first portion of the current blocking layer, and the electrode structure covers the first portion of the current blocking layer and contacts the upper surface of the semiconductor light-emitting sequence stacking layer through the first gap. The arrangement of the electrode structure enables the first portion of the current blocking layer to be completely contracted inside the electrode pad, and the edge of the lower surface of the electrode pad is directly in contact with the semiconductor light-emitting sequence stacking layer, thereby increasing an adhesive force of the electrode pad. During subsequent packaging and wire bonding, due to ductility of the electrode pad made from a metal material, the edge of the electrode pad can effectively buffer a force generated by the wire bonding to reduce a generated shear force, thereby reducing a stress exerted on the first portion of the current blocking layer during the wire bonding, reducing a breakage risk of the current blocking layer, and further reducing a risk that the electrode pad falls off due to the breakage of the current blocking layer.

In addition, at least the portion of the extension strip is formed on both of the second portion of the current blocking layer and the current expansion layer; and the part of the edge of the first opening of the current expansion layer is disposed on the second portion of the current blocking layer. The above arrangement of the current expansion layer further reduces the direct contact area between the electrode pad and the semiconductor light-emitting sequence stacking layer, which is beneficial to improving an extension capability of the current.

Moreover, the disclosure further defines that the absolute value of the width difference between the width of the first gap and the width of the second gap is not greater than 15 μm. By adjusting the width difference between the first gap and the second gap, the direct contact area between the electrode pad and the semiconductor light-emitting sequence stacking layer can be controlled, thereby preventing the current from being directly injected into the semiconductor light-emitting sequence stacking layer, improving the function of the current blocking layer, and ensuring that the current blocking layer is not broken due to the excessive stress during the wire bonding. Therefore, the wire bonding capability of the LED chip is improved and the reliability of the LED is promoted.

Other features and beneficial effects of the disclosure will be set forth in the following description. Therefore, partial content of the disclosure become obvious from the description, or be understood by implementing the disclosure.

### BRIEF DESCRIPTION OF DRAWINGS

FIG. 1 illustrates a schematic top view of a LED chip according to an embodiment 1 of the disclosure.

FIG. 2 illustrates a schematic enlarged view of a P portion shown in FIG. 1.

FIG. 3 illustrates a schematic sectional view of the LED chip along a section line A-A shown in FIG. 1.

FIG. 4 illustrates a schematic sectional view of the LED chip along a section line B-B shown in FIG. 1.

FIG. 5 illustrates a schematic sectional view of the LED chip along a section line B-C shown in FIG. 1.

FIG. 6 illustrates a schematic top view of a LED chip according to an illustrated embodiment in the embodiment 1 of the disclosure.

FIG. 7 illustrates a schematic top view of a LED chip according to an embodiment 2 of the disclosure.

FIG. 8 illustrates a schematic sectional view of the LED chip along a section line B1-B1 shown in FIG. 7.

FIG. 9A illustrates a schematic enlarged view of a P1 portion shown in FIG. 7.

FIG. 9B illustrates a schematic enlarged view of the P1 portion show in the FIG. 7 according to an illustrated embodiment in the embodiment 2 of the disclosure.

FIG. 10 illustrates a schematic top view of a LED chip according to an embodiment 3 of the disclosure.

FIG. 11 illustrates a schematic sectional view of the LED chip along a section line B2-B2 shown in FIG. 10.

FIG. 12 illustrates a schematic enlarged view of a P2 portion shown in FIG. 10.

FIG. 13 illustrates a schematic top view of a LED chip according to an embodiment 4 of the disclosure.

FIG. 14 illustrates a schematic sectional view of the LED chip along a section line B3-B3 shown in FIG. 13.

FIG. 15 illustrates a schematic enlarged view of a P3 portion shown in FIG. 13.

FIG. 16 illustrates a schematic top view of a LED chip according to an embodiment 5 of the disclosure.

FIG. 17 illustrates a schematic sectional view of the LED chip along a section line B4-B4 shown in FIG. 16.

FIG. 18 illustrates a schematic enlarged view of a P4 portion shown in FIG. 16.

FIG. 19 illustrates a schematic diagram of a light-emitting device according to an embodiment 6 of the disclosure.

Description of reference signs are as follows:
100—LED chip; 110—substrate; 120—semiconductor light-emitting sequence stacking layer; 121—first conductive semiconductor layer; 122—active layer; 123—second conductive semiconductor layer; 130—mesa structure; 140—current expansion layer; 141—first opening; 1411—outward expansion region; 150—current blocking layer; 151—first portion; 1511—local inward contraction region; 152—second portion; 160—second electrode; 161—electrode pad; 162—extension strip; 170—first electrode; 180—insulation protection layer; 181—second opening; 200—light-emitting device; 201—circuit substrate; 202—light-emitting component.

### DETAILED DESCRIPTION OF EMBODIMENTS

An implementation mode of the disclosure is described below through illustrated embodiments, and those skilled in the related art can easily understand other advantages and effects of the disclosure from the disclosed content of the disclosure. The disclosure may also be implemented or applied in different illustrated embodiments, and various details in the disclosure may also be modified or substituted based on different aspects and applications without departing from the spirit of the disclosure. In view of a contradiction between a capability of wire bonding of a LED and integrity of a current blocking layer in the related art, the disclosure provides a LED chip and a light-emitting device, which improves the reliability and current expansion capability of the LED chip to solve the above-mentioned contradiction.

In some embodiments, the LED chip includes: a semiconductor light-emitting sequence stacking layer; a current blocking layer that is formed on the semiconductor light-emitting sequence stacking layer and includes a first portion and a second portion; a current expansion layer that is formed on both of the semiconductor light-emitting sequence stacking layer and the second portion of the current blocking layer and defines a first opening, where the first portion of the current blocking layer is disposed in the first opening of the current expansion layer; and an electrode structure that includes an electrode pad and an extension strip.

Specially, a first gap is defined between the first portion of the current blocking layer and the current expansion layer; a second gap is defined between the first portion of the current blocking layer and the second portion of the current blocking layer; the electrode structure is disposed to cover the first portion of the current blocking layer and is in contact with an upper surface of the semiconductor light-emitting sequence stacking layer through the first gap; at least a portion of the extension strip is formed on both of the second portion of the current blocking layer and the current expansion layer; and a part of an edge of the first opening of the current expansion layer is disposed on the second portion of the current blocking layer.

The arrangement of the electrode structure enables the first portion of the current blocking layer to be completely contracted inside the electrode pad, and the edge of the lower surface of the electrode pad is directly in contact with the semiconductor light-emitting sequence stacking layer, thereby increasing an adhesive force of the electrode pad. During subsequent packaging and wire bonding, due to ductility of the electrode pad made from a metal material, the edge of the electrode pad can effectively buffer a force generated by the wire bonding to reduce a generated shear force, thereby reducing a stress exerted on the first portion of the current blocking layer during the wire bonding, reducing a breakage risk of the current blocking layer, and further reducing a risk that the electrode pad falls off due to the breakage of the current blocking layer.

In addition, at least the portion of the extension strip is formed on both of the second portion of the current blocking layer and the current expansion layer; and the part of the edge of the first opening of the current expansion layer is disposed on the second portion of the current blocking layer. The above arrangement of the current expansion layer enables an edge of the second portion of the current blocking layer to exceed an edge of the first opening of the current expansion layer, or the edge of the second portion of the current blocking layer is at least flush with the edge of the first opening of the current expansion layer, thereby reducing the direct contact area between the electrode pad and the semiconductor light-emitting sequence stacking layer, and facilitating the improvement of expansion capability of the current.

The disclosure further provides a LED chip, including the following components: a semiconductor light-emitting sequence stacking layer; a current blocking layer that is formed on the semiconductor light-emitting sequence stacking layer and includes a first portion and a second portion; a current expansion layer that is formed on the semiconductor light-emitting sequence stacking layer and defines a first opening, where the first portion of the current blocking layer being disposed in the first opening of the current expansion layer; and an electrode structure that includes an electrode pad and an extension strip. Specially, the electrode pad is disposed on the first portion of the current blocking layer, and the extension strip is formed on both of the second portion of the current blocking layer and the current expansion layer.

Specially, a first gap is defined between the first portion of the current blocking layer and the current expansion layer; a second gap is defined between the first portion of the current blocking layer and the second portion of the current blocking layer; and the electrode structure is disposed to cover the first portion of the current blocking layer and is in contact with an upper surface of the semiconductor light-emitting sequence stacking layer through the first gap; and an absolute value of a width difference between a width of the first gap and a width of the second gap is not greater than 15 μm. Through the above arrangement between the first gap and the second gap, the direct contact area between the electrode structure and the semiconductor light-emitting sequence stacking layer is reduced while the wire bonding capability of the LED chip is ensured, the current is prevented from being directly injected into the semiconductor light-emitting sequence stacking layer, and the effect of the current blocking layer is improved.

In some embodiments, a width of the first gap is greater than or equal to a width of the second gap. The first gap and the second gap are set in a connection area between the electrode pad and the extension strip, so that the direct contact area between the electrode structure and the semiconductor light-emitting sequence stacking layer can be reduced, thereby preventing the current from being directly injected into the semiconductor light-emitting sequence stacking layer, and improving the expansion capability of the current.

In some embodiments, the width of the second gap is greater than or equal to 0.5 μm. On the one hand, the width of the second gap is limited to prevent the current blocking layer at the connection area between the electrode pad and the extension strip from being subjected to greater force during the subsequent packaging and wire bonding due to that the width of the second gap is too small. Furthermore, the breakage of the current blocking layer at the contact area can be prevented, thereby avoiding a breakage at an area between the electrode pad and the extension strip. On the other hand, the width of the second gap is limited to ensure a photo process of the current blocking layer during etching, as well as ensure chemical etching of an insulation protection layer disposed on the electrode pad during subsequent etching, thereby reducing manufacturing difficulty of the LED chip.

Further, in some embodiments, the second portion of the current blocking layer extends into the first opening. The above arrangement further reduces the direct contact area between the electrode structure and the semiconductor light-emitting sequence stacking layer, improves the effect of the current blocking layer, and improves the current expansion capability.

Further, in some embodiments, the second portion of the current blocking layer extends below the electrode pad. In an illustrated embodiment, the direct contact area between the electrode structure and the semiconductor light-emitting sequence stacking layer is reduced, effectively improving the effect of the current blocking layer; meanwhile, the electrode pad can cover the current blocking layer that extends below the electrode pad, so that the current blocking layer can be protected from being damaged in the subsequent chemical etching process, the structural completion of the electrode pad is ensured, and the reliability of the LED chip is improved.

In some embodiments, an area of the first portion of the current blocking layer facing towards the second portion of the current blocking layer defines a local inward contraction region. That is, relative to other areas, in the area of the first portion of the current blocking layer facing towards the second portion of the current blocking layer, the first portion of the current blocking layer is further inward contracted relative to the edge of the first opening of the current expansion layer, so that a distance between the current blocking layer in the local inward contraction region and the edge of the first opening is greater than distances between the current blocking layer in the other areas and the edge of the first opening. The setting of local inward contraction region mentioned above increases an adjustable range of the width of the second gap, which is conducive to ensuring the photo process of the current blocking layer during the etching and the chemical etching when etching the insulation protection layer disposed on the electrode pad, thereby reducing the manufacturing difficulty of the LED chip.

Further, in some embodiments, the local inward contraction region is a fan shape. The local inward contraction region can solve a risk that when the second gap becomes much less, the manufacturing process is difficult, as well as a risk that when the second gap becomes much less, the connection between the electrode pad and the extension strip is easy to break.

In some embodiments, in an area of the current expansion layer facing towards the local inward contraction region, the current expansion layer extends into the first opening to define an outward expansion region. The formation of outward expansion region of the current expansion layer can further reduce the direct contact area between the electrode structure and the semiconductor light-emitting sequence stacking layer while ensuring the photo process of the current blocking layer during the etching and the chemical etching when etching the insulation protection layer disposed on the electrode pad, thereby preventing the current from being directly injected into the semiconductor light-emitting sequence stacking layer, and improving the expansion capability of the current.

Further, in some embodiments, the outward expansion region is an arc shape. The current expansion layer forms the outward expansion region at the area facing towards the local inward contraction region of the current blocking layer, which can solve the risk that when the second gap becomes much less, the manufacturing process of the LED chip is difficult, as well as the risk that the connection between the electrode pad and the extension strip is easy to break when the second gap becomes much less.

In some embodiments, the width of the first gap is greater than the width of the second gap.

In some embodiments, in the local inward contraction region, the width of the first gap is greater than or equal to the width of the second gap, and in an area of the first portion of the current blocking layer except for the local inward contraction region, the width of the first gap is greater than or equal to 0. The arrangement of the first gap may further control the direct contact area between the electrode structure and the semiconductor light-emitting sequence stacking layer, thereby further improving the current expansion capability.

In some embodiments, a projection area of the electrode pad of the electrode structure is less than or equal to or greater than a projection area of the first opening. The above arrangement of the electrode pad can ensure that there is no contact between the electrode pad and the current expansion layer in both horizontal and longitudinal directions, reducing the risk of unstable wire bonding caused by the weak adhesive force between the current expansion layer and the electrode pad during the subsequent packaging, improving the reliability of the LED chip, improving the current expansion efficiency of the extension strip and the current expansion layer, promoting diffusion and distribution of current to other areas outside the electrode pad, and enhancing the brightness of the LED chip. Furthermore, the current expansion layer can also be contracted into the electrode pad, which can effectively block etching solution when the insulation protection layer disposed on the electrode pad is etched subsequently, protecting the current blocking layer extending below the electrode pad from corrosion and damage, improving the completion of its structure, and thus enhancing the reliability of the LED chip.

In some embodiments, the semiconductor light-emitting sequence stacking layer includes a first conductive semiconductor layer, an active layer, and a second conductive semiconductor layer, and the electrode structure includes a first electrode electrically connected to the first conductive semiconductor layer and a second electrode electrically connected to the second conductive semiconductor layer.

In some embodiments, the LED chip further includes the insulation protection layer, and the insulation protection layer is at least disposed to cover parts of the electrode structure, the current blocking layer, and the current expansion layer.

In some embodiments, the first portion of the current blocking layer is a continuous structure or a discontinuous structure. When the first portion of the current blocking layer includes multiple separated blocks, the risk that the electrode pad falls off due to damage of the adhesive force of the electrode pad can be further reduced.

In some embodiments, the second portion of the current blocking layer includes multiple discontinuous portions, and the second gap is a minimum gap between the second portion of the current blocking layer and the first portion of the current blocking layer.

In some embodiments, the second portion of the current blocking layer is a continuous structure. When the second portion of the current blocking layer is the continuous structure, the function of the current blocking layer can be further improved, thereby improving the current expansion capability.

In some embodiments, the current blocking layer is a transparent insulation layer and is made from at least one of transparent inorganic insulation materials; the transparent inorganic insulation materials include: silicon dioxide, silicon nitride, silicon oxynitride, titanium dioxide, and aluminum oxide; and a thickness of the current blocking layer is in a range of 50 nanometers (nm) to 500 nm. The above material selection and thickness setting of the current blocking layer do not affect the light emission of the LED chip, and on the other hand, the current can be effectively prevented from flowing vertically into the second conductive semiconductor layer from an electrode disposed on the second conductive semiconductor layer, which is beneficial to improving the expansion capability of the current.

The disclosure further provides a light-emitting device, including: a circuit substrate and a light-emitting component disposed on the circuit substrate, and the light-emitting component includes the LED chip provided in any one of the above embodiments. The light-emitting device using the LED chip has good reliability and light-emitting effect.

The technical solutions of the disclosure will be clearly and completely described below with reference to attached drawings of the embodiments of the disclosure through various illustrated embodiments.

### Embodiment 1

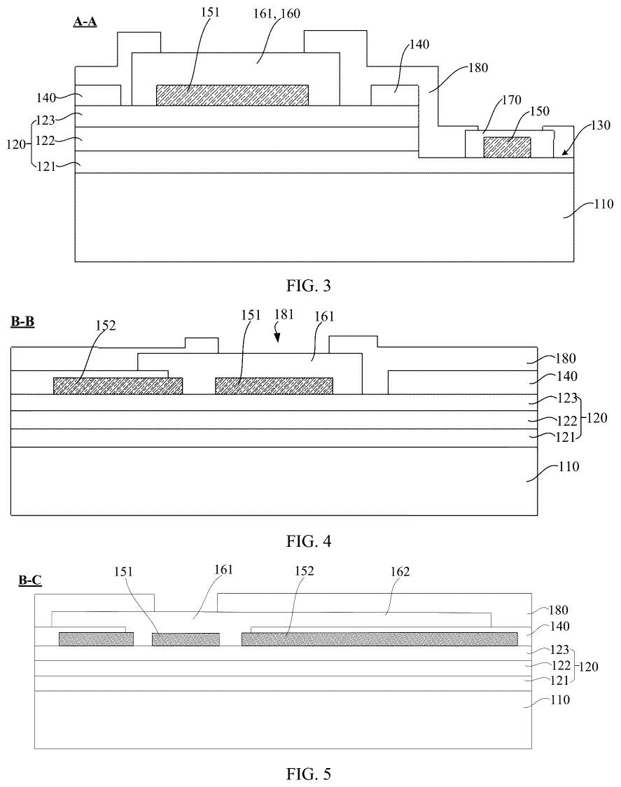

With reference to FIG. 1 and FIG. 3, a LED chip 100 of the present embodiment includes a substrate 110 and a semiconductor light-emitting sequence stacking layer 120 formed on the substrate 110, which may be a sapphire substrate, a sapphire patterned substrate, a gallium nitride substrate, an aluminum nitride substrate, a silicon carbide substrate, a silicon substrate, or etc., and in an illustrated embodiment, the substrate 110 is the sapphire patterned substrate. The semiconductor light-emitting sequence stacking layer 120 includes a first conductive semiconductor layer 121, an active layer 122, and a second conductive semiconductor layer 123 stacked on the substrate 110. Specially, the first conductive semiconductor layer 121 may be an n-type layer (referred to a negative layer conductive by electrons) or a p-type layer (referred to a positive layer conductive by electron holes), and the second conductive semiconductor layer 123 is a p-type layer or an n-type layer corresponding to the first conductive semiconductor layer 121. In the present embodiment, the first conductive semiconductor layer 121 is the n-type layer and the second conductive semiconductor layer 123 is the p-type layer. Specially, the n-type semiconductor layer may be a silicon-doped gallium nitride layer, the p-type semiconductor layer may be a magnesium-doped gallium nitride layer, and the active layer 122 may be a single heterostructure, a double heterostructure, a double-sided heterostructure, or a multi-layer quantum well. Moreover, the active layer 122 can be made of an intrinsic semiconductor (I-type semiconductor), a p-type semiconductor, or an n-type semiconductor, and in the present embodiment, the active layer 122 includes a layer of the multi-layer quantum well. In an illustrated embodiment, the LED chip 100 is a normal chip, as shown in FIG. 3, the LED chip 100 is formed with a mesa structure 130, the mesa structure 130 is formed on the first conductive semiconductor layer 121 to expose the first conductive semiconductor layer 121, and a sidewall of the mesa structure 130 exposes the second conductive semiconductor layer 123 and the active layer 122. In an illustrated embodiment, the sidewall of the mesa structure 130 may further expose a portion of the first conductive semiconductor layer.

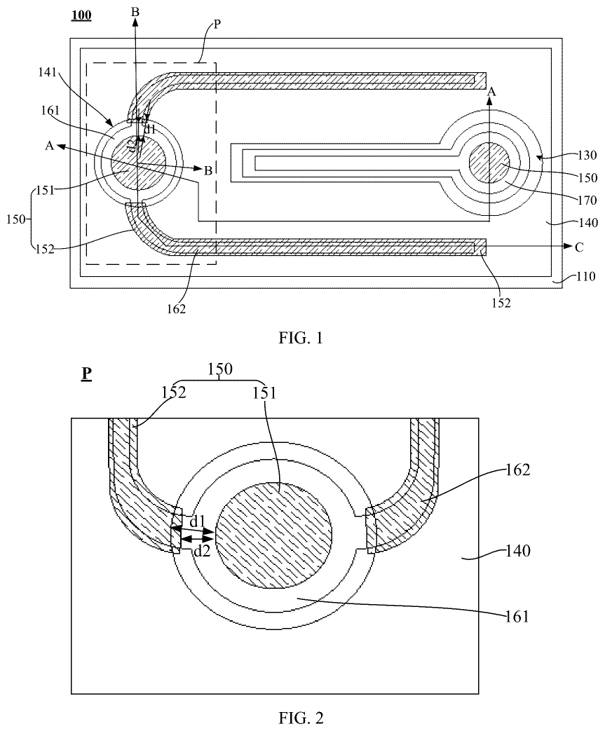

With reference to FIG. 1, FIG. 2, and FIG. 3 to FIG. 5, the LED chip 100 further includes a current expansion layer 140, a current blocking layer 150, and an electrode structure. The current blocking layer 150 includes a first portion 151 and a second portion 152. Moreover, a first gap dl is defined between the first portion 151 of the current blocking layer 150 and the current expansion layer 140, and a second gap d2 is defined between the first portion 151 of the current blocking layer 150 and the second portion 152 of the current blocking layer 150. The current expansion layer 140 is disposed on both of the semiconductor light-emitting sequence stacking layer 120 and the second portion 152 of the current blocking layer 150. In an illustrated embodiment, the current expansion layer 140 further covers a surface of the first conductive semiconductor layer 121 exposed by the mesa structure 130. The current expansion layer 140 defines a first opening 141, and the first portion 151 of the current blocking layer 150 is disposed in the first opening 141 of the current expansion layer 140. The electrode structure includes a first electrode 170 and a second electrode 160 electrically connected to the first conductive semiconductor layer 121 and the second conductive semiconductor layer 123, respectively. The electrode structure generally further includes an electrode pad 161 and an extension strip 162 connected to the electrode pad 161. In the present embodiment, the following description takes the second electrode 160 as an example, which can be understood that the first electrode 170 is made by the same structure. In an illustrated embodiment, the current expansion layer 140 is a transparent conductive layer, that is, a conductive material having a transparent property, including thin metals such as gold and nickel, or oxides of metals such as zinc, indium, and tin, and specially, the current expansion layer 140 is indium tin oxide (ITO). The electrode structure is made from at least one of gold, silver, copper, aluminum, chromium, nickel, titanium and platinum, or at least one of an alloy or a stack of the above materials.

With reference to FIG. 2 and FIG. 3 to FIG. 5, the electrode structure covers the first portion 151 of the current blocking layer 150, and contacts the upper surface of the semiconductor light-emitting sequence stacking layer 120 through the first gap d1; at least a portion of the extension strip 162 is formed on both of the second portion 151 of the current blocking layer 150 and the current expansion layer 140; and a part of an edge of the first opening 141 of the current expansion layer 140 is disposed on the second portion 152 of the current blocking layer 150. The electrode pad 161 is formed at a position corresponding to the first opening 141 of the current expansion layer 140, and the first portion 151 of the current blocking layer 150 is formed within the first opening 141. The first portion 151 of the current blocking layer 150 covers the second conductive semiconductor layer 123 exposed by the first opening 141, and the first gap d1 is defined between the first portion 151 of the current blocking layer 150 and the current expansion layer 140, that is, the first portion 151 of the current blocking layer 150 is completely accommodated in the first opening 141, and the current expansion layer 140 is not overlapped. The electrode pad 161 of the electrode structure is formed on the current blocking layer 150 to fill the first gap d1, and the electrode pad 161 directly contacts the upper surface of the second conductive semiconductor layer 123 through the first gap d1. Therefore, the first portion 151 of the current blocking layer 150 is completely contracted inside the electrode pad 161, and the edge portion of the lower surface of the electrode pad 161 is directly in contact with the semiconductor light-emitting sequence stacking layer 120, thereby increasing the adhesive force of the electrode pad 161. During the subsequent packaging and wire bonding, due to the ductility of the metal material forming the electrode pad 161, the edge portion of the electrode pad 161 can effectively buffer the wire bonding force and reduce the shear force, thereby reducing the stress exerted on the first portion 151 of the current blocking layer 150 during the wire bonding, reducing the risk of crushing the current blocking layer 150, and further reducing the risk that the electrode pad 161 falls off due to the crushing of the current blocking layer 150. In an illustrated embodiment, the current blocking layer 150 is made from at least one of transparent insulation materials such as silicon dioxide, silicon nitride, silicon oxynitride, titanium dioxide, and aluminum oxide. The current blocking layer 150 can be a single-layer structure, a multilayer structure, or a repeatedly overlapping multilayer structure, such as a distributed Bragg reflective layer. In an illustrated embodiment, the current blocking layer 150 is a silicon dioxide layer with a thickness in a range of 50 nm to 500 nm, and further, the thickness of the current blocking layer 150 is in a range of 120 nm to 450 nm.

In an illustrated embodiment, the second gap d2 is defined between the first portion 151 of the current blocking layer 150 and the second portion 152 of the current blocking layer 150, at least a portion of the first gap d1 is greater than or equal to the second gap d2, that is, the first gap d1 can all be greater than the second gap d2, or the portion of the first gap d1 is greater than the second gap d2, and another portion of the first gap d1 is equal to the second gap d2.

In the present embodiment, with reference to FIG. 1, FIG. 2, and FIG. 4, the second portion 152 of the current blocking layer 150 extends into the first opening 141, but the electrode pad 161 does not cover the area of the second portion 152 extending into the first opening 141, that is, as shown in FIG. 1, FIG. 2, and FIG. 4, the edge of the first opening 141 is disposed on the second portion 152 of the current blocking layer 150. The second gap d2 is defined between the second portion 152 of the current blocking layer 150 and the first portion 151 of the current blocking layer 150, and a width of the second gap d2 is completely smaller than that of the first gap d1. The electrode pad 161 of the electrode structure is formed on the current blocking layer 150 and fills the first gap d1, and it can be understood that the electrode pad 161 is simultaneously filled in the second gap d2. The electrode pad 161 in the first gap d1 is in direct contact with the second conductive semiconductor layer 123. As shown in FIG. 2, a projection area of the electrode pad 161 is greater than a projection area of the first portion 151 of the current blocking layer 150 and smaller than a projection area of the first opening 141. In the present embodiment, in a region where the electrode pad 161 is connected to the extension strip 162, an absolute value of a width difference between the first gap d1 and the second gap d2 is not greater than 15 μm, and in an illustrated embodiment, the width difference is in a range of 4 μm to 7 μm. In an illustrated embodiment, the width of the second gap d2 is controlled to be greater than or equal to 0.5 μm; and in an illustrated embodiment, the width of the second gap d2 is between 2 μm and 6 μm, and further, the width of the second gap d2 is between 3 um and 5 μm, i.e., 2 μm, 3 μm or 3.5 μm, 2.5 μm, 5 μm, 6 μm, etc. The arrangement of the second gap d2 reduces the direct contact area between the electrode pad 161 and the second conductive semiconductor layer 123, thereby increasing the blocking effect of the current blocking layer 150, and improving the efficiency of the current blocking layer 150 during the subsequent wire bonding.

With reference to FIG. 1 to FIG. 5, in an illustrated embodiment, the second portion 152 of the current blocking layer 150 is formed as a continuous structure, for example, formed into a continuous strip-shaped structure, so as to block the current in the electrode extension strip 162 from directly diffusing into the semiconductor light-emitting sequence stacking layer 120 below the electrode extension strip 162, thereby increasing the expansibility of the current.

In an illustrated embodiment, as shown in FIG. 6, the second portion of the current blocking layer 150 may also be formed as a discontinuous structure, for example, formed into multiple block structures. Therefore, the second gap d2 refers to a gap between the second portion 152 closest to the first portion 151 and the first portion 151. The multiple block structures can be rectangular structures, triangular structures, cylindrical structures, etc.

With reference to FIG. 2 to FIG. 5, in the present embodiment, the first portion 151 of the current blocking layer 150 is formed as the continuous structure, such as a columnar structure. Therefore, as shown in FIG. 2, the first gap d1 defined between the first portion 151 of the current blocking layer 150 and the current expansion layer 140 refers to a gap defined between the edge of the first portion 151 and the current expansion layer 140 along a radial direction, and the second gap d2 refers to a gap defined between the edge of the first portion 151 and the second portion 152 along the radial direction.

In another illustrated embodiment, the first portion 151 of the current blocking layer 150 can also be formed as the discontinuous structure. For example, the first portion 151 can include a central columnar structure and an annular column separated from the central columnar structure and nested on an outer side of the central columnar structure. Therefore, the first gap d1 refers to a gap defined between an outer edge of the outer annular column and the current expansion layer 140 along the radial direction, and the second gap d2 refers to a gap defined between the outer edge of the annular column and the second portion 152 along the radial direction. Alternatively, the first portion 151 can be a hollow annular columnar structure, and at the same time, the first gap d1 refers to a gap defined between an outer edge of the hollow annular columnar structure and the current expansion layer 140 along the radial direction, and the second gap d2 refers to a gap defined between the outer edge of the hollow annular columnar structure and the second portion 152 along the radial direction. Alternatively, the first portion 151 can include multiple fan-shaped structures arranged at intervals. Therefore, the multiple fan-shaped structures are disposed corresponding to the second portion 152 rather than the intervals of the multiple fan-shaped structures. At the same time, the first gap d1 refers to a gap defined between an outer edge of a fan-shaped structure of the multiple fan-shaped structures and the current expansion layer 140 along the radial direction, and the second gap d2 refers to a gap defined between the outer edge of the fan-shaped structure and the second portion 152 along the radial direction. Alternatively, the first portion 151 can include a central columnar structure and multiple fan-shaped structures distributed around the central columnar structure and spaced apart from the central columnar structure, and the multiple fan-shaped structures are spaced with equal intervals apart from each other. Therefore, the multiple fan-shaped structures are disposed corresponding to the second portion 152 rather than the intervals of the multiple fan-shaped structures. At this time, the first gap d1 refers to a gap defined between an outer edge of a fan-shaped structure of the multiple fan-shaped structures and the current expansion layer 140 along the radial direction, and the second gap d2 refers to a gap defined between the outer edge of the fan-shaped structure and the second portion 152 along the radial direction. Alternatively, the first portion 151 can include multiple columnar structures spaced apart from each other, and specially, the multiple columnar structures are distributed along an extending direction of the second portion 152. Therefore, the first gap dl refers to a gap defined between an edge of a side of the columnar structure facing towards the second portion 152 and the current expansion layer 140 along the radial direction, and the second gap d2 refers to a gap defined between the edge of the side of the columnar structure facing towards the second portion 152 and the second portion 152 along the radial direction.

With reference to FIG. 2 to FIG. 5 again, the LED chip 100 further includes an insulation protection layer 180 covering a surface of the LED chip 100, that is, the surface and the sidewall of the mesa structure 130, and the exposed surfaces of the current expansion layer 140, and the extension strip 162 of the electrode structure, to protect the LED chip 100. The insulation protection layer 180 defines a second opening 181 at a position corresponding to the electrode pad 161 to expose the electrode pad 161, which facilitates the subsequent wire bonding. The second opening 181 is generally formed by the following method: forming a photoresist layer on the insulation protection layer 180, forming a window pattern at a position in the photoresist layer corresponding to the electrode pad 161 by a the photo process, and etching the insulation protection layer 180 by using the etching solution through the window pattern to form the second opening 181. The setting of the first gap d1 and the second gap d2 in the present embodiment ensures the pattern windows in the photo process and the chemical etching process, reducing the difficulty of etching, simultaneously reducing the risk of disconnection between the extension strip 162 and the electrode pad 161. Moreover, during the wire bonding, the force exerted on the first portion 151 of the current blocking layer 150 below the electrode pad 161 can be reduced, thereby reducing the risk of breakage of the current blocking layer 150, and thus reducing the risk of breakage of the electrode pad 161, improving the reliability of the LED chip 100.

### Embodiment 2

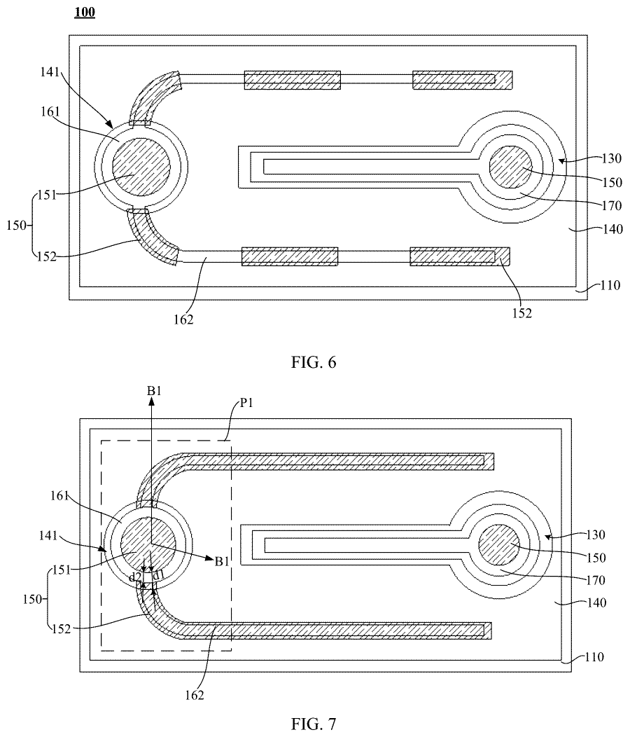

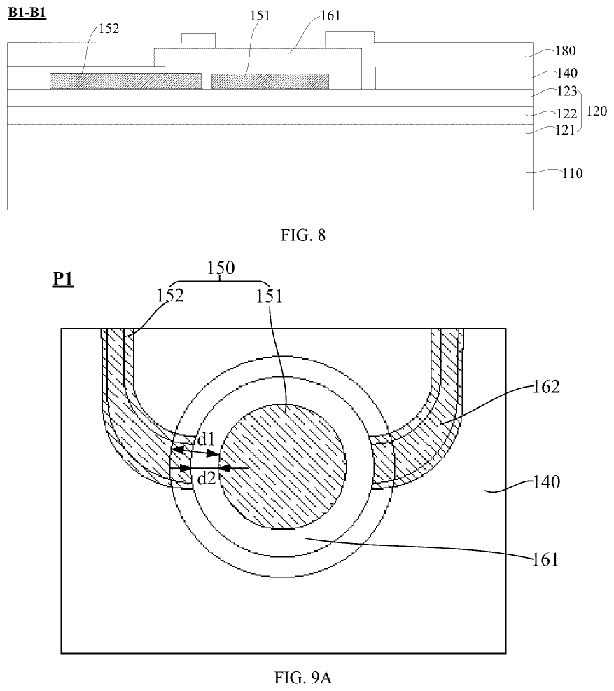

The present embodiment also provides a LED chip 100, as shown in FIG. 7 to FIG. 9A, and differences between the LED 100 of the present embodiment and the LED chip 100 of the embodiment 1 are as follows.

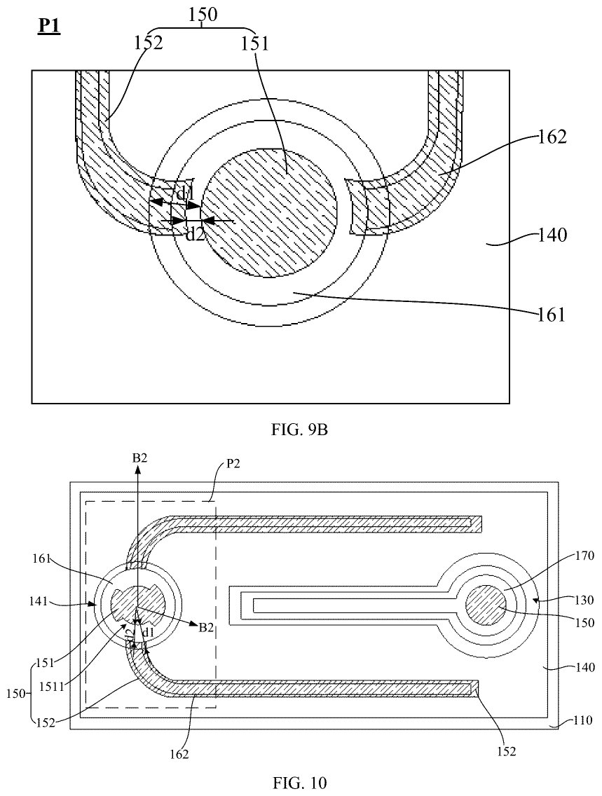

In present embodiment, the second portion 152 of the current blocking layer 150 further extends into the first opening 141 of the current expansion layer 140, which can further reduce the direct contact area between the electrode structure and the semiconductor light-emitting sequence stacking layer 120, improve the function of the current blocking layer 150, and improve the current expansion capability. In an illustrated embodiment, the edge of the second portion 152 is flush with an edge of the electrode pad 161. Alternatively, as shown in FIG. 9B, the electrode pad 161 of the electrode structure can further extend into the second portion 150 of the current blocking layer 150 disposed in the first opening 141. The second gap d2 defined between the second portion 152 and the first portion 151 is completely smaller than the first gap d1 defined between the first portion 151 and the current expansion layer 140. Specially, the second gap d2 defined between the second portion 152 and the first portion 151 is controlled to be 2 μm to 6 μm, and further, between 3 μm and 5 μm, i.e., 2 μm, 3 μm or 3.5 μm, 2.5 μm, 5 μm, 6 μm, etc. The electrode pad 161 covers the second portion 152 extending into the first opening 141, reducing the direct contact area between the electrode pad 161 and the second conductive semiconductor layer 123, increasing the contact area between the electrode pad 161 and the second portion 152 of the current blocking layer 150, increasing the current blocking effect of the current blocking layer 150, and improving the current expansion effect, making horizontal distribution of the current more uniform, which is conducive to improving the light-emitting effect of the LED chip 100. The edge of the electrode pad 161 is flush with the edge of the second portion 152, or the electrode pad 161 further covers the second portion 152 extending into the first opening 141, which can protect the current blocking layer 150 from damage during the subsequent chemical etching process, ensure the structural integrity of the current blocking layer 150, and improve the reliability of the LED chip 100.

### Embodiment 3

The present embodiment also provides a LED chip 100, as described in the embodiment 2, when the second portion 152 of the current blocking layer 150 extends into the first opening 141, and the electrode pad 161 is disposed to cover the second portion 152, the second gap d2 defined between the second portion 152 and the first portion 151 maybe too small, which can cause the following problems. When the insulation protection layer 180 is etched to define the second opening 181, the second gap d2 is smaller, the photo process and development process become more difficult, and the synchronous chemical etching is also difficult. When the second gap d2 becomes smaller, in the subsequent wire bonding, the force exerted on the current blocking layer 150 in the second gap d2 is greater, which also increases the risk of breaking the current blocking layer 150, causing the extension strip 162 to disconnect from the electrode pad 161, affecting the reliability of the LED chip 100. In order to prevent the above problem, the present embodiment further designs the LED chip 100 according to the embodiment 2, specifically including the following steps.

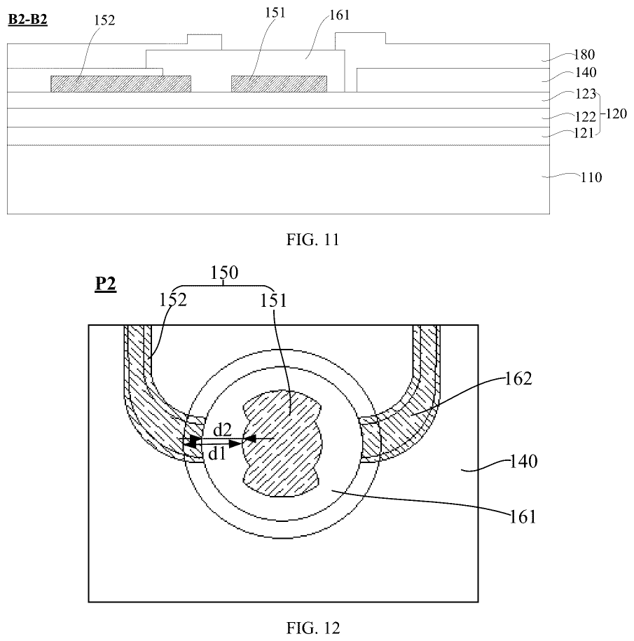

In the present embodiment, with reference to FIG. 10 to FIG. 12, the second gap d2 defined between the second portion 152 and the first portion 151 is also completely smaller than the first gap d1 defined between the first portion 151 and the current expansion layer 140. Specially, in the LED chip 100 of the present embodiment, the second portion 152 of the current blocking layer 150 also extends into the first opening 141, the edge of the second portion 152 is flush with the edge of the electrode pad 161, or the electrode pad 161 covers the second portion 152 of the current blocking layer 150 extending into the first opening 141. In the present embodiment, the first portion 151 of the current blocking layer 150 defines a local inward contraction region 1511 in an area of the first portion 151 extending into the first opening 141 facing towards the second portion 152, that is, a size (for example, a diameter) of the first portion 151 of the current blocking layer 150 corresponding to the local inward contraction region 1511 is smaller than a size (for example, a diameter) of a remaining portion of the first portion 151. At the same time, the local inward contraction region 1511 is a fan-shaped structure, that is, a diameter of the fan-shaped structure is equal to that a diameter of the remaining portion of the first portion 151 of the current blocking layer 150 corresponding to the local inward contraction region 1511 minus a diameter of the first portion 151 of the current blocking layer 150 corresponding to the local inward contraction region 1511. The arrangement of the local inward contraction region 1511 increases the adjustable range of the second gap d2, so that the second gap d2 is controlled to be between 2 μm and 6 μm, and further, between 3 μm and 5 μm, i.e., 2 μm, 3 μm or 3.5 μm, 2.5 μm, 5 μm, 6 μm, etc. Therefore, the stress exerted on the current blocking layer 150 in the second gap d2 can be optimized while the light-emitting effect of the LED chip 100 is improved, the current blocking layer 150 is prevented from being broken, then the electrode pad 161 and the extension strip 162 are prevented from being broken, and the reliability of the LED chip 100 is improved.

### Embodiment 4

The present embodiment also provides a LED chip 100; as described in the above embodiments 1-3, the projection area of the first opening 141 of the current expansion layer 140 is greater than the projection area of the electrode pad 161, and the electrode pad 161 is fully accommodated in the first opening 141; and the second portion 152 of the current blocking layer 150 extends below the electrode pad 161. When the second opening 181 is formed by subsequent wet etching of the insulation protection layer 180, the etching solution will immerse along the edge of the electrode pad 161 into the current blocking layer 150 around the electrode pad 161, and the current blocking layer 150 around the electrode pad 161 will be etched to form a small pit. In order to prevent the above-mentioned problem, the present embodiment further designs the LED chip 100, specifically including the following steps.

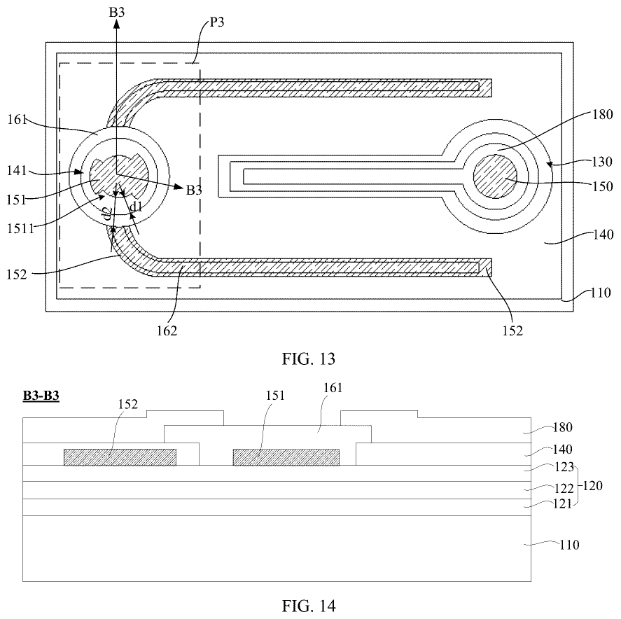

With reference to FIG. 13 to FIG. 15, in the present embodiment, the electrode pad 161 is not only formed in the first opening 141, but also formed outside the first opening 141, that is, filling the first gap d1 defined between the current expansion layer 140 and the first portion 151 as well as the second gap d2 defined between the first portion 151 and the second portion 152. That is, the projection area of the electrode pad 161 is greater than that of the first opening 141. In an illustrated embodiment, the distance between the edge of the electrode pad 161 and the edge of the first opening 141 is about 2 μm, i.e., in a range of 2 μm to 5 μm. At the same time, a contact area between the electrode pad 161 and the current expansion layer 140 greatly increases, enhancing the lateral expansion of the current and improving the light-emitting effect of the light-emitting diode (i.e., contained in the LED chip 100). Moreover, when the second opening 181 is formed by the subsequent etching on the insulation protection layer 180, the etching solution can be prevented from infiltrating the current blocking layer 150 around the electrode pad 161, ensuring the integrity of the current blocking layer 150, improving the blocking effect of the current blocking layer 150, and promoting the reliability of the LED chip 100.

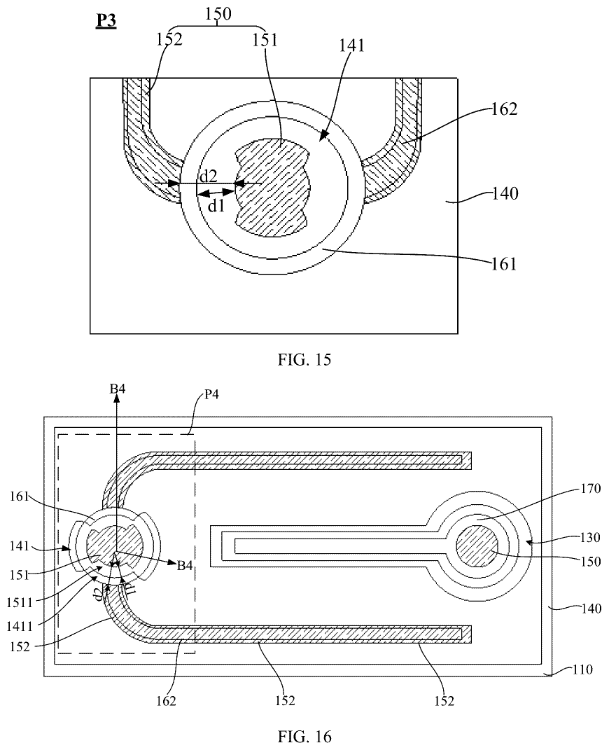

Alternatively, in the present embodiment, as shown in FIG. 15, the edge of the second portion 152 of the current blocking layer 150 is also flush with the edge of the electrode pad 161; or the edge of the second portion 152 is disposed below the electrode pad 161. Therefore, the second portion 152 does not extend into the first opening 141, the second portion 152 is flush with the sidewall of the current expansion layer 140 disposed on the edge of the first opening 141; or there is a certain distance existed between the second portion 152 and the edge of the first opening 141. The area of the first portion 151 of the current blocking layer 150 facing towards the second portion 152 defines the local inward contraction region 1511. As shown in FIG. 15, when the edge of the second portion 152 is flush with the edge of the electrode pad 161, in the local inward contraction region, the first gap d1 defined between the first portion 151 of the current blocking layer 150 and the current expansion layer 140 is smaller than the second gap d2 defined between the first portion 151 and the second portion 152. Alternatively, when there is the certain distance existed between the second portion 152 of the current blocking layer 150 and the edge of the first opening 141, in the local inward contraction region, the first gap d1 defined between the first portion 151 of the current blocking layer 150 and the current expansion layer 140 is smaller than the second gap d2 defined between the first portion 151 and the second portion 152. When the second portion 152 is flush with the side wall of the current expansion layer 140 disposed in the edge of the first opening 141, in the local inward contraction region 1511, the first gap d1 is equal to the second gap d2. In an illustrated embodiment, in an area outside the local inward contraction region 1511, the first portion 151 of the current blocking layer 150 can completely fill the first opening 141, that is, in the area outside the local inward contraction region 1511, the side wall of the first portion 151 overlap with the side wall of the current expansion layer 140. The above arrangement can further increase the contact area between the current expansion layer 140 and the electrode pad 161, thereby enhancing the current expansion capability.

### Embodiment 5

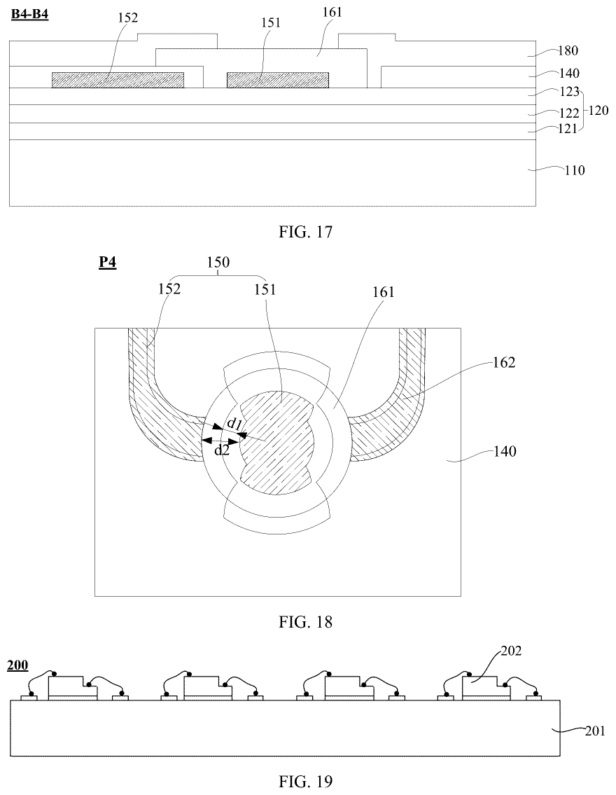

The present embodiment also provides a LED chip 100. Unlike the LED chip 100 provided in the embodiment 3, as shown in FIG. 16 to FIG. 18, in the present embodiment, the area of the first portion 151 of the current blocking layer 150 facing towards the second portion 152 of the current blocking layer 150 defines the local inward contraction region 1511. In an area of the current expansion layer 140 facing towards the local inward contraction region 1511, the current expansion layer 140 extends into the first opening 141 to define an outward expansion region 1411. At the same time, the first opening 141 is irregular, and an opening size (such as a diameter) of the outward expansion region 1411 is smaller than a size (such as a diameter) of a remaining portion of the first opening 141. The outward expansion region 1411 is an arc shape. A projection of the electrode pad 161 on the outward expansion region 1411 is disposed outside the first opening 141, and an area of the first portion 151 of the current blocking layer 150 except for the outward expansion region 1411 is disposed inside the first opening 141. As shown in FIG. 16 and FIG. 18, the edge of the second portion 152 of the current blocking layer 150 is also flush with the edge of the electrode pad 161; or, in an illustrated embodiment, the second portion 152 of the current blocking layer 150 continues to extend along the edge of the electrode pad 161 but does not extend into the first opening 141, that is, an end portion of the edge of the second portion 152 is disposed outside the edge of the first opening 141 or flush with the edge of the first opening 141. Therefore, the electrode pad 161 covers the end portion of the edge of the second portion 152 of the current blocking layer 150. In the present embodiment, in the local inward contraction region 1511, the first gap d1 defined between the first portion 151 of the current blocking layer 150 and the current expansion layer 140 is smaller than the second gap d2 defined between the first portion 151 and the second portion 152. Alternatively, when there is the certain distance existed between the second portion 152 of the current blocking layer 150 and the edge of the first opening 141, the first gap d1 defined between the first portion 151 of the current blocking layer 150 and the current expansion layer 140 in the local inward contraction region 1511 is smaller than the second gap d2 defined between the first portion 151 and the second portion 152; and when the end portion of the edge of the second portion 152 is flush with the edge of the first opening 141, in the local inward contraction region 1511, the first gap d1 is equal to the second gap d2.

The above design greatly increases the contact area between the electrode pad 161 and the current expansion layer 140 at the outward expansion region 1411, enhances the lateral expansion of the current, and is beneficial to improving the light-emitting effect of the LED. In addition, when the insulation protection layer 180 is subsequently etched to form the second opening 181, the etching solution can be effectively prevented from immersing into the current blocking layer 150 around the electrode pad 161, thereby ensuring the integrity of the current blocking layer 150 and improving the blocking effect thereof, which is beneficial to improving the reliability of the LED chip 100. At the same time, it is also ensured that the edge portion of the lower surface of the electrode pad 161 disposed in the remaining area of the first opening 141 except for the outward expansion region 1411 is directly in contact with the semiconductor light-emitting sequence stacking layer 120, thereby increasing the adhesive force of the electrode pad 161.

### Embodiment 6

The present embodiment provides a light-emitting device 200, the light-emitting device 200 includes a circuit substrate 201 and a light-emitting component 202 disposed on the circuit substrate 201, and the light-emitting component 202 can be the LED chip 100 provided in the embodiment 1 and/or the embodiment 2 and/or the embodiment 3 and/or the embodiment 4 and/or the embodiment 5 of the present disclosure. A light-emitting surface of the LED chip 100 of the embodiment 1, the embodiment 2 and the embodiment 3 has the above structure, so that the light-emitting device 200 also has a good light-emitting effect, i.e. reliability.

The above-mentioned embodiments are merely illustrative of the principles and effects of the disclosure, but are not intended to limit the disclosure. Those skilled in the related art can modify or change the above embodiments without departing from the spirit and scope of the disclosure. Therefore, all equivalent modifications or changes made by those skilled in the related art without departing from the spirit and technical ideas disclosed in the disclosure shall still be covered by the disclosure.

What is claimed is:

1. A light-emitting diode (LED) chip, comprising:
a semiconductor light-emitting sequence stacking layer;
a current blocking layer, formed on the semiconductor light-emitting sequence stacking layer, wherein the current blocking layer comprises a first portion and a second portion;
a current expansion layer, formed on the semiconductor light-emitting sequence stacking layer and the second portion of the current blocking layer, wherein the current expansion layer defines a first opening, and the first portion of the current blocking layer is disposed in the first opening of the current expansion layer; and
an electrode structure, wherein the electrode structure comprises an electrode pad and an extension strip;
wherein a first gap is defined between the first portion of the current blocking layer and the current expansion layer; a second gap is defined between the first portion of the current blocking layer and the second portion of the current blocking layer; the electrode structure is disposed to cover the first portion of the current blocking layer and is in contact with an upper surface of the semiconductor light-emitting sequence stacking layer through the first gap; at least a portion of the extension strip is formed on the second portion of the current blocking layer and the current expansion layer; and a part of an edge of the first opening of the current expansion layer is disposed on the second portion of the current blocking layer.

2. The LED chip as claimed in claim 1, wherein a width of the first gap is greater than or equal to a width of the second gap.

3. The LED chip as claimed in claim 1, wherein a width of the second gap is greater than or equal to 0.5 micrometers (μm).

4. The LED chip as claimed in claim 1, wherein the second portion of the current blocking layer extends into the first opening.

5. The LED chip as claimed in claim 1, wherein the second portion of the current blocking layer extends below the electrode pad.

6. The LED chip as claimed in claim 5, wherein an area of the first portion of the current blocking layer facing towards the second portion of the current blocking layer defines a local inward contraction region.

7. The LED chip as claimed in claim 6, wherein the local inward contraction region is a fan shape.

8. The LED chip as claimed in claim 6, wherein in an area of the current expansion layer facing towards the local inward contraction region, the current expansion layer extends into the first opening to define an outward expansion region.

9. The LED chip as claimed in claim 8, wherein the outward expansion region is an arc shape.

10. The LED chip as claimed in claim 4, wherein a width of the first gap is greater than a width of the second gap.

11. The LED chip as claimed in claim 6, wherein in the local inward contraction region, a width of the first gap is greater than or equal to a width of the second gap, and in an area of the first portion of the current blocking layer except for the local inward contraction region, the width of the first gap is greater than or equal to 0.

12. The LED chip as claimed in claim 1, wherein a projection area of the electrode pad of the electrode structure is less than or equal to or greater than a projection area of the first opening.

13. The LED chip as claimed in claim 1, wherein the semiconductor light-emitting sequence stacking layer comprises a first conductive semiconductor layer, an active layer, and a second conductive semiconductor layer, and the electrode structure comprises a first electrode electrically connected to the first conductive semiconductor layer and a second electrode electrically connected to the second conductive semiconductor layer.

14. The LED chip as claimed in claim 1, further comprising: an insulation protection layer, wherein the insulation protection layer is at least disposed to cover parts of the electrode structure, the current blocking layer, and the current expansion layer.

15. The LED chip as claimed in claim 1, wherein the first portion of the current blocking layer is a continuous structure or a discontinuous structure.

16. The LED chip as claimed in claim 1, wherein the second portion of the current blocking layer comprises a plurality of discontinuous portions, and the second gap is a minimum gap between the second portion of the current blocking layer and the first portion of the current blocking layer.

17. The LED chip as claimed in claim 1, wherein the second portion of the current blocking layer is a continuous structure.

18. The LED chip as claimed in claim 1, wherein the current blocking layer is a transparent insulation layer and is made from at least one of transparent inorganic insulation materials; the transparent inorganic insulation materials comprise: silicon dioxide, silicon nitride, silicon oxynitride, titanium dioxide, and aluminum oxide; and a thickness of the current blocking layer is in a range of 50 nanometers (nm) to 500 nm.

19. A LED chip, comprising:
a semiconductor light-emitting sequence stacking layer;
a current blocking layer, formed on the semiconductor light-emitting sequence stacking layer, wherein the current blocking layer comprises a first portion and a second portion;
a current expansion layer, formed on the semiconductor light-emitting sequence stacking layer and the second portion of the current blocking layer, wherein the current expansion layer defines a first opening, and the first portion of the current blocking layer is disposed in the first opening of the current expansion layer; and
an electrode structure, wherein the electrode structure comprises an electrode pad and an extension strip; the electrode pad is disposed on the first portion of the current blocking layer, and the extension strip is formed on the second portion of the current blocking layer and the current expansion layer;
wherein a first gap is defined between the first portion of the current blocking layer and the current expansion layer;
wherein a second gap is defined between the first portion of the current blocking layer and the second portion of the current blocking layer; and
wherein the electrode structure is disposed to cover the first portion of the current blocking layer and is in contact with an upper surface of the semiconductor light-emitting sequence stacking layer through the first gap; and an absolute value of a width difference between a width of the first gap and a width of the second gap is not greater than 15 μm.

20. A light-emitting device, comprising a circuit substrate and a light-emitting component disposed on the circuit substrate, wherein the light-emitting component comprises the LED chip as claimed in claim 1.
